(19) United States
(12) Patent Application Publication
(10) Pub. No.: US 2023/0146059 A1
(43) Pub. Date: May 11, 2023

(54) ELECTRONIC DEVICE

(71) Applicant: InnoLux Corporation, Miao-Li County (TW)

(72) Inventor: Yu-Heng CHEN, Miao-Li County (TW)

(73) Assignee: InnoLux Corporation, Miao-Li County (TW)

(21) Appl. No.: 17/963,204

(22) Filed: Oct. 11, 2022

(30) Foreign Application Priority Data
Nov. 10, 2021 (CN) 202111328841.1

(51) Int. Cl. H01L 31/0352; H01L 31/0224

(52) U.S. Cl. CPC H01L 31/03529; H01L 31/022408; H01L 31/035281

(57) ABSTRACT

An electronic device includes a substrate; a first electrode layer disposed on the substrate; a first insulating layer disposed on the first electrode layer, having a first opening to expose a surface of the first electrode layer; a connecting layer, wherein at least a portion of the connecting layer is disposed in the first opening, a sidewall exposure of the first opening is exposed, and the connecting layer is electrically connected to the first electrode layer; a second insulating layer disposed on the first insulating layer, having a second opening to expose a surface of the connecting layer; and a second electrode layer disposed on the second insulating layer, wherein at least a portion of the second electrode layer is disposed in the second opening, and is electrically connected to the connecting layer.

### CROSS REFERENCE TO RELATED APPLICATION

This application claims the benefit of China Patent Application No. 202111328841.1, filed on Nov. 10, 2021, the entire content of which is incorporated herein by reference.

### BACKGROUND OF THE DISCLOSURE

### 1. Field of the Disclosure

The present disclosure relates to an electronic device, and more particularly to an electronic device with a connecting layer in an opening of an insulating layer.

### 2. Description of the Prior Art

Display devices include the majority of electronic devices. With ongoing developments in this field, the connection between the various electrode layers within a display device is an important issue. The thicker an insulating layer, the deeper an opening of the insulating layer, making a connection between two electrode layers via the opening of the insulating layer less simple. When there are more than two insulating layers, aligning the openings between all the insulating layers needs to be considered. This may complicate the manufacturing processes. Thus, it is necessary to provide an electronic device having a higher connection reliability of electrode layers that can be formed with simpler manufacturing processes.

### SUMMARY OF THE DISCLOSURE

The present disclosure therefore provides an electronic device to solve the abovementioned problem.

The electronic device includes a substrate; a first electrode layer disposed on the substrate; a first insulating layer disposed on the first electrode layer, having a first opening to expose a surface of the first electrode layer; a connecting layer, wherein at least a portion of the connecting layer is disposed in the first opening, a sidewall exposure of the first opening is exposed, and the connecting layer is electrically connected to the first electrode layer; a second insulating layer disposed on the first insulating layer, having a second opening to expose a surface of the connecting layer; and a second electrode layer disposed on the second insulating layer, wherein at least a portion of the second electrode layer is disposed in the second opening, and is electrically connected to the connecting layer.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1A is a side view of a pixel along a tangent line in an electronic device according to some embodiments of the present disclosure.

FIG. 1B is a top view of a plurality of pixels in an electronic device according to some embodiments of the present disclosure.

FIG. 2A is a side view of a pixel along tangent lines in an electronic device according to some embodiments of the present disclosure.

FIG. 2B is a top view of a plurality of pixels in an electronic device according to some embodiments of the present disclosure.

FIG. 3A is a side view of a pixel along tangent lines in an electronic device according to some embodiments of the present disclosure.

FIG. 3B is a top view of a plurality of pixels in an electronic device according to some embodiments of the present disclosure.

FIG. 4A is a side view of a pixel along tangent lines in an electronic device according to some embodiments of the present disclosure.

FIG. 4B is a top view of a plurality of pixels in an electronic device according to some embodiments of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of an electronic device in this disclosure, and certain elements in various drawings may not be drawn to scale. In addition, the number and dimension of each device shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components that differ in name but not function.

In the following description and in the claims, the terms “include”, “comprise” and “have” are used in an open-ended fashion, and thus should be interpreted to mean “include, but not limited to . . . ”.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for explaining and not used for limiting the present disclosure. Regarding the drawings, the drawings show the general characteristics of methods, structures, and/or materials used in specific embodiments. However, the drawings should not be construed as defining or limiting the scope or properties encompassed by these embodiments. For example, for clarity, the relative size, thickness, and position of each layer, each area, and/or each structure may be reduced or enlarged.

It will be understood that, when the corresponding component such as layer or area is referred to “on another component”, it may be directly on this another component, or other component(s) may exist between them (indirect case). On the other hand, when the component is referred to “directly on another component (or the variant thereof)”, any component does not exist between them. “electrically connected to” another element or layer can be directly electrically connected to the other element or layer, or intervening elements or layers may be presented. The terms of “jointed” and “connected” may also include cases where both structures are movable or both structures are fixed.

The terms “equal”, or “same” generally mean within 20% of a given value or range, or mean within 10%, 5%, 3%, 2%, 1%, or 0.5% of a given value or range.

The phrase “in a range from a first value to a second value” indicates the range includes the first value, the second value, and other values in between.

Although terms such as first, second, third, etc., may be used to describe diverse constituent elements, such constituent elements are not limited by the terms. These terms are used only to discriminate a constituent element from other constituent elements in the specification, and these terms have no relation to the manufacturing order of these constituent components. The claims may not use the same terms, but instead may use the terms first, second, third, etc. with respect to the order in which an element is claimed. Accordingly, in the following description, a first constituent element may be a second constituent element in a claim.

It is noted that the technical features in different embodiments described in the following can be replaced, recombined or mixed with one another to constitute another embodiment without departing from the spirit of the present disclosure.

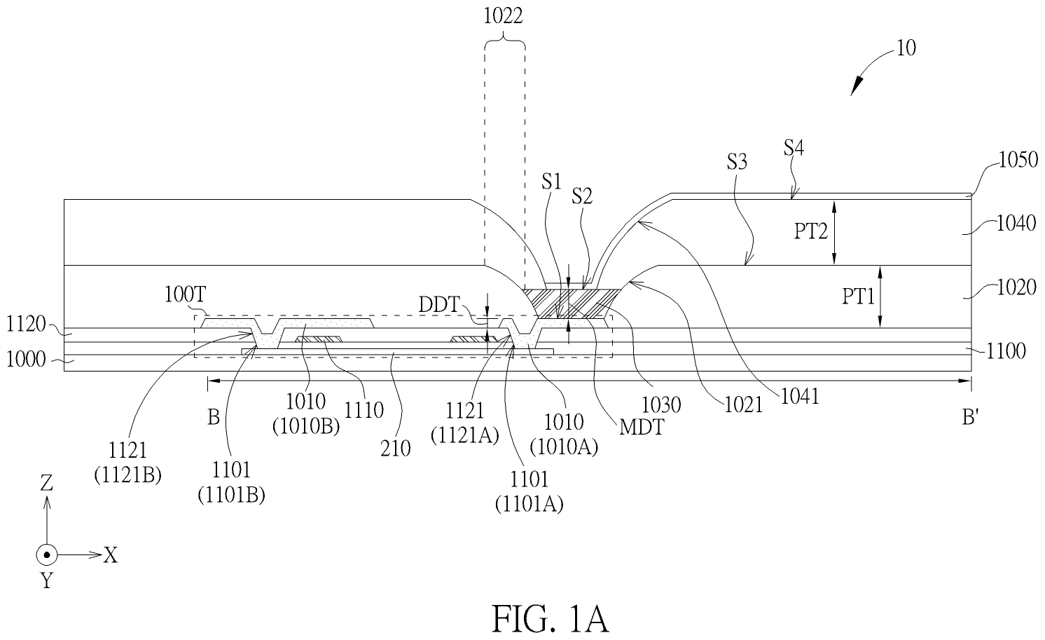

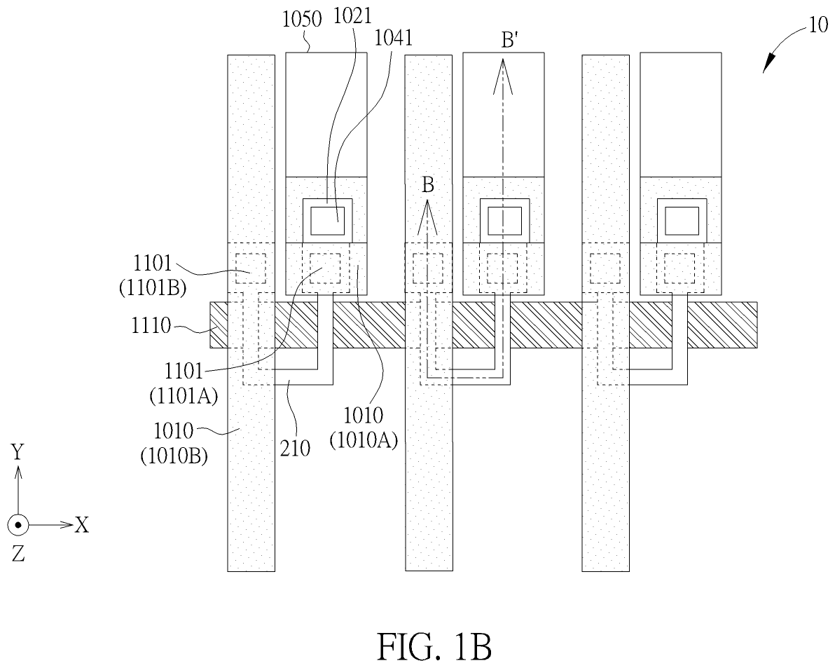

FIG. 1A is a side view of a pixel along a tangent line B-B′ shown in FIG. 1B in an electronic device 10 according to some embodiments of the present disclosure. FIG. 1B is a top view of a plurality of pixels in the electronic device 10 according to some embodiments of the present disclosure, wherein the pixel in which the tangent line B-B′ is drawn may correspond to the pixel in FIG. 1A.

As shown in FIG. 1A, the X axis, Y axis and Z axis are perpendicular to each other, wherein the Z axis is a normal direction of a substrate 1000. The electronic device 10 may include the substrate 1000, a first electrode layer 1010A, a first insulating layer 1020, a connecting layer 1030, a second insulating layer 1040 and a second electrode layer 1050. The first electrode layer 1010A may be disposed on the substrate 1000. The first insulating layer 1020 may be disposed on the first electrode layer 1010A, and may have a first opening 1021 to expose a surface S1 of the first electrode layer 1010A. The first opening 1021 may be a hole or a groove on the first insulating layer 1020. The first opening 1021 may have a depth and a width. At least a portion of the connecting layer 1030 may be disposed in the first opening 1021, and a sidewall exposure 1022 of the first opening 1021 may be exposed, i.e. the portion of the connecting layer 1030 may not fill the first opening 1021. The connecting layer 1030 may be electrically connected to the first electrode layer 1010A. The second insulating layer 1040 may be disposed on the first insulating layer 1020, and may have a second opening 1041 to expose a surface S2 of the connecting layer 1030. The second opening 1041 may be a hole or a groove on the second insulating layer 1040. The second opening 1041 may have a depth and a width. The second electrode layer 1050 may be disposed on the second insulating layer 1040. At least a portion of the second electrode layer 1050 may be disposed in the second opening 1041, and may be electrically connected to the connecting layer 1030. In the present disclosure, a range of the opening of the insulating layer shown in the top view is the bottom of the opening in the corresponding side view.

According to some embodiments, the second electrode layer 1050 may be electrically connected to the first electrode layer 1010A in a driving component 100T via the connecting layer 1030 disposed in the first opening 1021. For example, according to some embodiments, the first electrode layer 1010A may be an electrode in the driving component 100T (e.g. a transistor). For example, the first electrode layer 1010A may be a drain in the driving element 100T. The second electrode layer 1050 may be a pixel electrode. Thus, the pixel electrode 1050 may be electrically connected to the first electrode layer 1010A in the driving component 100T via the connecting layer 1030 disposed in the first opening 1021. A detailed description follows. A semiconductor layer 210, a gate line 1110, an insulating layer 1100 and an insulating layer 1120 may be disposed on the substrate 1000. The insulating layer 1100 may have an insulating layer opening 1101. The insulating layer 1120 may have an insulating layer opening 1121. According to some embodiments, the insulating layer opening 1121 may include an opening 1121A and an opening 1121B. The insulating layer opening 1101 may include an opening 1101A and an opening 1101B. A conductive layer 1010 may be patterned to form the first electrode layer 1010A and a signal line 1010B. The signal line 1010B may be a data line. The first electrode layer 1010A (drain) may be disposed in the insulating layer opening 1101A and the insulating layer opening 1121A, to thereby be electrically connected to the semiconductor layer 210. The data line 1010B may be disposed in the insulating layer opening 1101B and the insulating layer opening 1121B, to thereby be electrically connected to the semiconductor layer 210. Thus, the semiconductor layer 210, the first electrode layer 1010A (drain), a portion of the data line 1010B and a portion of the gate line 1110 may constitute the driving component 100T.

In some embodiments, the substrate 1000, the first electrode layer 1010A, the first insulating layer 1020, the first opening 1021, the connecting layer 1030, the second insulating layer 1040, the second opening 1041 and the second electrode layer 1050 may be sequentially disposed in the electronic device 10. That is, the connecting layer 1030 is disposed before the second insulating layer 1040 is disposed. By disposing the connecting layer 1030 before disposing the second insulating layer 1040, the second electrode layer 1050 may be connected to (e.g. electrically connected to or contacting) the connecting layer 1030 via the second opening 1041, and the connecting layer 1030 may be connected to the first electrode layer 1010A via the first opening 1021.

As shown in FIG. 1A, at least a portion of the second insulating layer 1040 may be disposed in the first opening 1021. At least a portion of the second insulating layer 1040 may be disposed on (e.g. covers) the sidewall exposure 1022. In some embodiments, as shown in FIG. 1A and FIG. 1B, the first opening 1021 may overlap the second opening 1041. The first opening 1021 may be equal to, greater than, or smaller than the second opening 1041, but is not limited thereto. In some embodiments, the width of the first opening 1021 may be 4-8 micrometers (μm), and the width of the second opening 1041 may be 4-8 μm. FIG. 1B shows that the first opening 1021 is greater than the second opening 1041; this is only an embodiment of the present disclosure and is not intended to limit the present disclosure. According to some embodiments, the first opening 1021 and the second opening 1041 may be aligned or non-aligned. In the present disclosure, two openings being aligned means that centers of the two openings overlap, and two openings being non-aligned means that the centers of the two openings do not overlap.

According to some embodiments, as shown in FIG. 1A, at least a portion of the connecting layer 1030 is disposed in the first opening 1021 of the first insulating layer 1020 and is electrically connected to the first electrode layer 1010A. The second opening 1041 of the second insulating layer 1040 exposes the surface S2 of the connecting layer 1030. Thus, at least a portion of the second electrode layer 1050 is disposed in the second opening 1041 of the second insulating layer 1040, and is electrically connected to the first electrode layer 1010A via the connecting layer 1030 disposed in the first opening 1021 of the first insulating layer 1020. Thus, the second electrode layer 1050 does not need to be directly connected to the first electrode layer 1010A via the two openings of the two insulating layers. In this way, connection between the two electrode layers may have a higher reliability. According to some embodiments, the first opening 1021 and the second opening 1041 may not need to be aligned, which may simplify the manufacturing processes.

According to some embodiments, the first insulating layer 1020 and the second insulating layer 1040 may include an organic material, an inorganic material or combination thereof, but is not limited thereto. According to some embodiments, the first insulating layer 1020 and the second insulating layer 1040 may include the organic material. The organic material may include epoxy resins, silicone, acrylic resins (e.g. polymethylmetacrylate (PMMA)), polyimide, perfluoroalkoxy alkane (PFA) or combination thereof, but is not limited thereto. Furthermore, the first insulating layer 1020 and the second insulating layer 1040 may serve as a planarization layer.

In some embodiments, the insulating layer 1100 may include a gate insulator (GI), but is not limited thereto. According to some embodiments, the insulating layer 1120 may include an interlayer dielectric (ILD), but is not limited thereto.

In some embodiments, the substrate 1000 may include a rigid substrate, a flexible substrate or combination thereof, but is not limited thereto. For example, the substrate 1000 may include a glass, a quartz, a sapphire, acrylic resins, polycarbonate (PC), polyimide (PI), polyethylene terephthalate (PET), other suitable transparent materials or any combination thereof, but is not limited thereto. In some embodiments, the semiconductor layer 210 may include polysilicon, amorphous silicon or metal oxide, but is not limited thereto.

The thickness in the present disclosure refers to a distance from the bottom to the top of a component or a layer along the Z axis. For example, a thickness PT1 of the first insulating layer 1020 is a distance from a side of the first insulating layer 1020 close to the substrate 1000 to a side of the first insulating layer 1020 close to the second insulating layer 1040 along the Z axis. In some embodiments, a thickness MDT of the connecting layer 1030 may be 9,000-30,000 Angstrom (Å), but is not limited thereto. In some embodiments, the thickness of the connecting layer 1030 may be greater than a thickness of the first electrode layer 1010A. The thickness of the connecting layer 1030 may be greater than a thickness of the second electrode layer 1050. In some embodiments, the connecting layer 1030 may include one or more thick film conductive layers, but is not limited thereto. In some embodiments, the thickness PT1 of the first insulating layer 1020 may be 10,000-31,000 Å, but is not limited thereto. In some embodiments, a thickness PT2 of the second insulating layer 1040 may be 10,000-31,000 Å, but is not limited thereto. In some embodiments, a thickness DDT of the first electrode layer 1010A may be 2,000-6,000 Å, but is not limited thereto. In some embodiments, a thickness DDT of the conductive layer 1010 may be 2,000-6,000 Å, but is not limited thereto.

As shown in FIG. 1B, the X axis, Y axis and Z axis are perpendicular to each other, wherein the Z axis is the normal direction of the substrate 1000. Refer to FIG. 1A for a disposal of the electronic device 10 in FIG. 1B, and details are not repeated herein. It is noted that the second electrode layer 1050 is connected to the first electrode layer 1010A via the connecting layer 1030 in FIG. 1A (not shown in FIG. 1B). The first opening 1021 is greater than the second opening 1041.

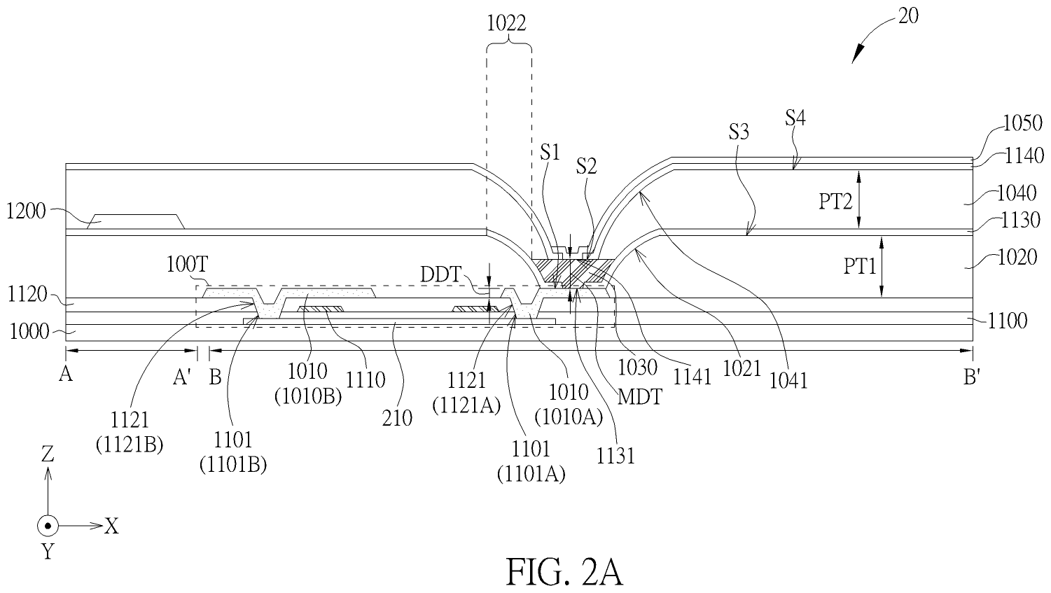

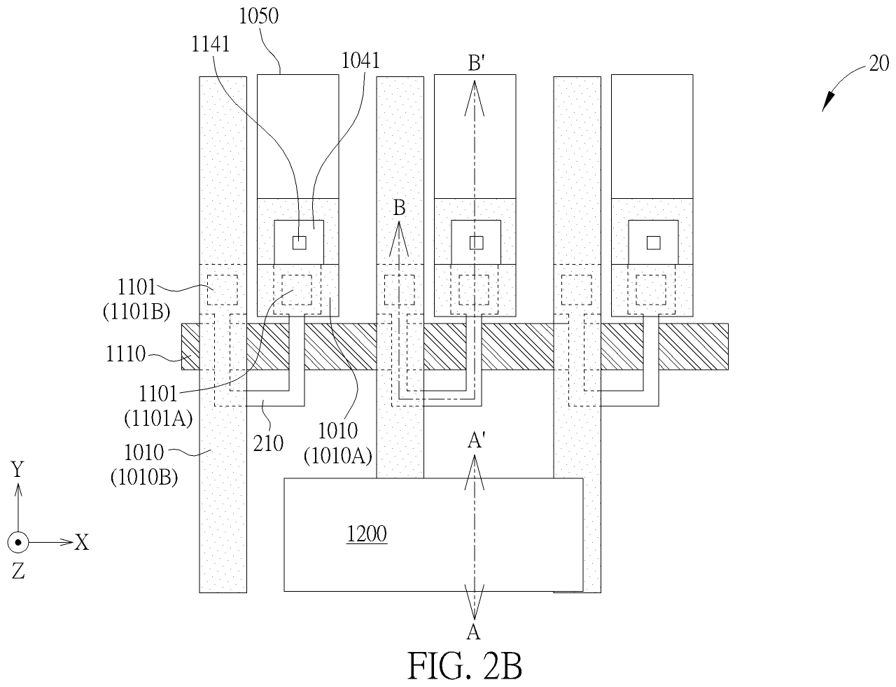

FIG. 2A is a side view of a pixel along tangent lines A-A′ and B-B′ in an electronic device 20 according to some embodiments of the present disclosure. FIG. 2B is a top view of a plurality of pixels in the electronic device 20 according to some embodiments of the present disclosure, wherein the pixel in which the tangent lines A-A′ and B-B′ are drawn may correspond to the pixel in FIG. 2A.

Compared with FIG. 1A, the main difference between the embodiments of FIG. 2A and FIG. 1A is that a third insulating layer 1130 and a fourth insulating layer 1140 are added. As shown in FIG. 2A, X axis, the Y axis and Z axis are perpendicular to each other, wherein the Z axis is the normal direction of the substrate 1000. Compared with FIG. 1A, the third insulating layer 1130 may be disposed on the first insulating layer 1020 and may have a third opening 1131. The third opening 1131 may be a hole or a groove on the third insulating layer 1130. The third opening 1131 may have a depth and a width. The third opening 1131 may be disposed in the first opening 1021. For example, at least a portion of the third insulating layer 1130 may be disposed in the first opening 1021. At least a portion of the connecting layer 1030 may be disposed in the third opening 1131. The fourth insulating layer 1140 may be disposed on the second insulating layer 1040 and may have a fourth opening 1141. The fourth opening 1141 may be a hole or a groove on the fourth insulating layer 1140. The fourth opening 1141 may have a specific depth and width. The fourth opening 1141 may be disposed in the second opening 1041. At least a portion of the second electrode layer 1050 may be disposed in the fourth opening 1141. According to some embodiments, the thickness of the first insulating layer 1120 may be greater than a thickness of the third insulating layer 1130. The thickness of the first insulating layer 1120 may be greater than a thickness of the fourth insulating layer 1140. According to some embodiments, the thickness of the second insulating layer 1040 may be greater than the thickness of the third insulating layer 1130. The thickness of the second insulating layer 1040 may be greater than the thickness of the fourth insulating layer 1140.

As shown in FIG. 2A, the third opening 1131 of the third insulating layer 1130 may expose the surface S1 of the first electrode layer 1010A. The fourth opening 1141 of the fourth insulating layer 1140 may expose the surface S2 of the connecting layer 1030. Thus, at least a portion of the second electrode layer 1050 disposed in the second opening 1041 may be electrically connected to the first electrode layer 1010A below the connecting layer 1030 via at least a portion of the connecting layer 1030 disposed in the first opening 1021. The fourth opening 1141 of the fourth insulating layer 1140 may be disposed in the second opening 1041 of the second insulating layer 1040. The third openings 1131 of the third insulating layer 1130 may be disposed in the first openings 1021 of the first insulating layer 1020. Thus, the second electrode layer 1050 may be connected to the connecting layer 1030 via the fourth opening 1141 in the second opening 1041, and the connecting layer 1030 may be connected to the first electrode layer 1010A via the third opening 1131 in the first opening 1021, so that the second electrode layer 1050 and the first electrode layer 1010A are electrically connected. Thus, the second electrode layer 1050 does not need to be directly connected to the first electrode layer 1010A via the two openings of the two insulating layers. Thus, according to some embodiments of the present disclosure, as shown in FIG. 1A, the alignment of the first opening 1021 and the second opening 1041 does not need to be considered, which may simplify the manufacturing process.

The light sensing component 1200 may be disposed on the first insulating layer 1020. In detail, according to some embodiments, the light sensing component 1200 may be disposed between the first insulating layer 1020 and the second insulating layer 1040. According to some embodiments, the light sensing component 1200 may be disposed between the third insulating layer 1130 and the second insulating layer 1040. According to some embodiments, the light sensing component 1200 may be electrically connected to another driving component (not shown) according to design requirements. The other driving component may be disposed on the substrate 1000.

According to some embodiments, the third insulating layer 1130 and the fourth insulating layer 1140 may be an organic material, an inorganic material or a combination thereof, but is not limited thereto. According to some embodiments, the third insulating layer 1130 and the fourth insulating layer 1140 may be the inorganic material. The inorganic material may include Silicon nitride, Silica, Silicon oxynitride, Al2O3, HfO2 or any combination thereof, but is not limited thereto. Furthermore, the third insulating layer 1130 and the fourth insulating layer 1140 may serve as a passivation layer.

In the prior art, the second electrode layer 1050 needs to be connected to the first electrode layer 1010A via the fourth opening 1141 of the fourth insulating layer 1140 in an absence of the connecting layer 1030. Since there is a thicker second insulating layer 1040 below the fourth insulating layer 1140, during a process of forming the opening of the fourth insulating layer 1140 by using a photoresist via a lithography process, photoresist residues may easily be formed, resulting in poor electrical connection between the second electrode layer 1050 and the first electrode layer 1010A. According to some embodiments of the present disclosure, however, as shown in FIG. 2A, at least a portion of the connecting layer 1030 is disposed in the first opening 1021. Thus, during the process of forming the opening of the fourth insulating layer 1140 by using the photoresist via the lithography process, the problem of the photoresist residues can be avoided, so that the poor electrical connection between the second electrode layer 1050 and the first electrode layer 1010A can be prevented.

In some embodiments, the light sensing component 1200 may include a photodiode or may include a PIN diode or a NIP diode having an undoped intrinsic semiconductor region between the p-type semiconductor and the n-type semiconductor. The light sensing component 1200 may convert a received light into a current signal. In terms of function, the light sensing component 1200 may be a biometric identification component, such as a fingerprint identification component or a palmprint identification component.

As shown in FIG. 2A, the substrate 1000, the first electrode layer 1010A, the first insulating layer 1020, the first opening 1021, the third insulating layer 1130, the third opening 1131, the connecting layer 1030, the light sensing component 1200, the second insulating layer 1040, the second opening 1041, the fourth insulating layer 1140, the fourth opening 1141 and the second electrode layer 1050 may be sequentially disposed in the electronic device 20. That is, the connecting layer 1030 is disposed before the second insulating layer 1040 is disposed. By disposing the connecting layer 1030 before disposing the second insulating layer 1040, the second electrode layer 1050 may be connected to the connecting layer 1030 via the second opening 1041 and/or the fourth opening 1141. The connecting layer 1030 may be connected to the first electrode layer 1010A via the first opening 1021 and/or the third opening 1131. Similarly, by disposing the connecting layer 1030, the fourth opening 1141 may be indirectly connected to the third opening 1131 via the connecting layer 1030. Thus, the fourth opening 1141 and the third opening 1131 may not be aligned.

As shown in FIG. 2B, the X axis, Y axis and Z axis are perpendicular to each other, wherein the Z axis is the normal direction of the substrate 1000. Refer to FIG. 2A for a disposal of the electronic device 20 in FIG. 2B, and details are not repeated herein. For the simplicity of the figures, only the second opening 1041 (of the first opening 1021 and the second opening 1041 in FIG. 2A) is shown in FIG. 2B. The first opening 1021 may be greater than the second opening 1041, the first opening 1021 may be smaller than the second opening 1041 or the first opening 1021 may be equal to the second opening 1041. In addition, only the fourth opening 1141 (of the third opening 1131 and the fourth opening 1141 in FIG. 2A) is shown in FIG. 2B. The third opening 1131 may be greater than the fourth opening 1141, the third opening 1131 may be smaller than the fourth opening 1141 or the third opening 1131 may be equal to the fourth opening 1141. It is noted that the second electrode layer 1050 is connected to the first electrode layer 1010A via the connecting layer 1030 in FIG. 2A (not shown in FIG. 2B). The second opening 1041 may be greater than the fourth opening 1141.

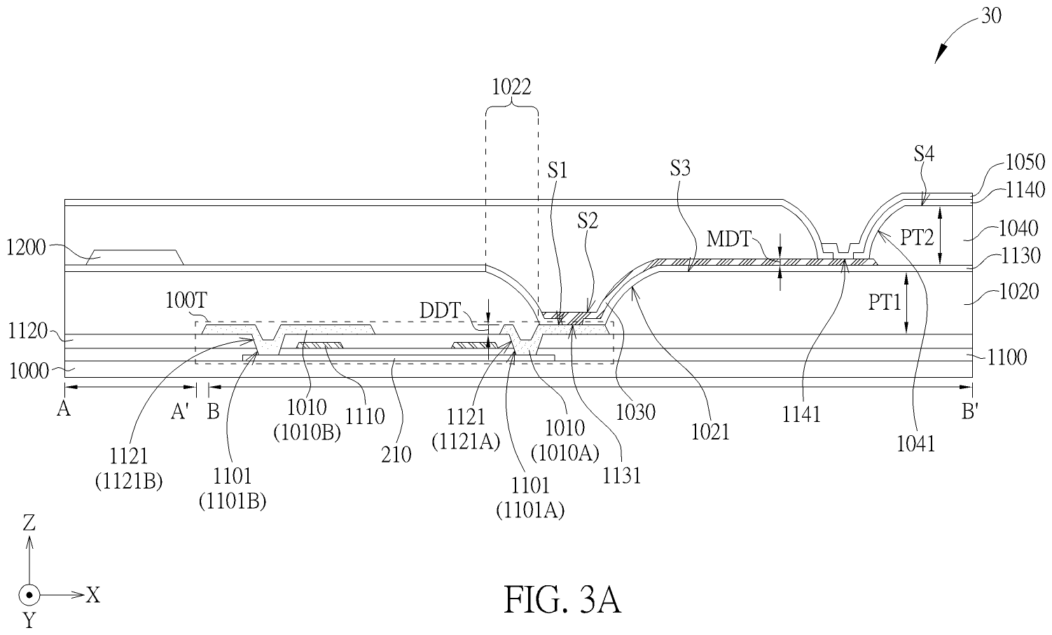

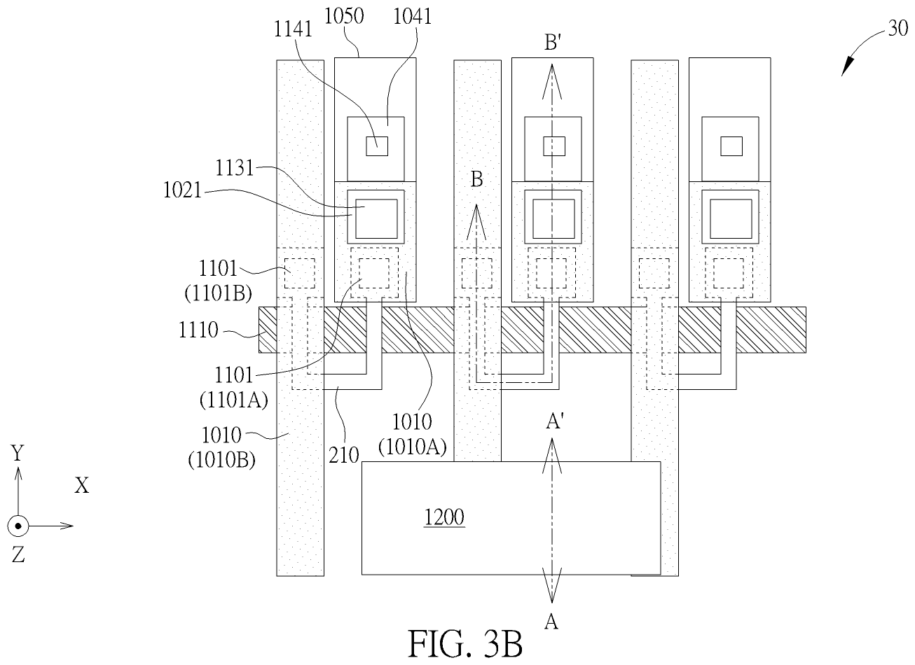

FIG. 3A is a side view of a pixel along tangent lines A-A′ and B-B′ in an electronic device 30 according to some embodiments of the present disclosure. FIG. 3B is a top view of a plurality of pixels in the electronic device 30 according to some embodiments of the present disclosure, wherein the pixel in which the tangent lines A-A′ and B-B′ are drawn may correspond to the pixel in FIG. 3A.

As shown in FIG. 3A, the X axis, Y axis and Z axis are perpendicular to each other, wherein the Z axis is the normal direction of the substrate 1000. Compared to FIG. 2A, in FIG. 3A, the first opening 1021 may not overlap the second opening 1041. Furthermore, in FIG. 3A, the first opening 1021 and the second opening 1041 are not aligned; that is, the center of the first opening 1021 and the center of the second opening 1041 do not overlap. At least a portion of the connecting layer 1030 may be disposed in the first opening 1021. At least another portion of the connecting layer 1030 may be disposed (e.g. may extend) below the second opening 1041 and/or the fourth opening 1141. According to some embodiments, as shown in FIG. 3A, the portion of the connecting layer 1030 may be disposed on a surface S3 of the first insulating layer 1020.

As shown in FIG. 3A, the substrate 1000, the first electrode layer 1010A, the first insulating layer 1020, the first opening 1021, the third insulating layer 1130, the third opening 1131, the connecting layer 1030, the light sensing component 1200, the second insulating layer 1040, the second opening 1041, the fourth insulating layer 1140, the fourth opening 1141 and the second electrode layer 1050 may be sequentially disposed in the electronic device 30. That is, the connecting layer 1030 is disposed before the second insulating layer 1040 is disposed. By disposing the connecting layer 1030 before disposing the second insulating layer 1040, the second electrode layer 1050 may be connected to the connecting layer 1030 via the second opening 1041 and/or the fourth opening 1141. The connecting layer 1030 may be connected to the first electrode layer 1010A via the first opening 1021 and/or the third opening 1131. Similarly, by disposing the connecting layer 1030, the fourth opening 1141 and the third opening 1131 do not overlap and are not directly connected. Thus, the fourth opening 1141 and the third opening 1131 may not be aligned.

As shown in FIG. 3B, the X axis, Y axis and Z axis are perpendicular to each other, wherein the Z axis is the normal direction of the substrate 1000. Refer to FIG. 3A for a disposal of the electronic device 30 in FIG. 3B, and details are not repeated herein. It is noted that the second electrode layer 1050 is connected to the first electrode layer 1010A via the connecting layer 1030 in FIG. 3A (not shown in FIG. 3B). The first opening 1021 does not overlap the second opening 1041. The third opening 1131 does not overlap the fourth opening 1141.

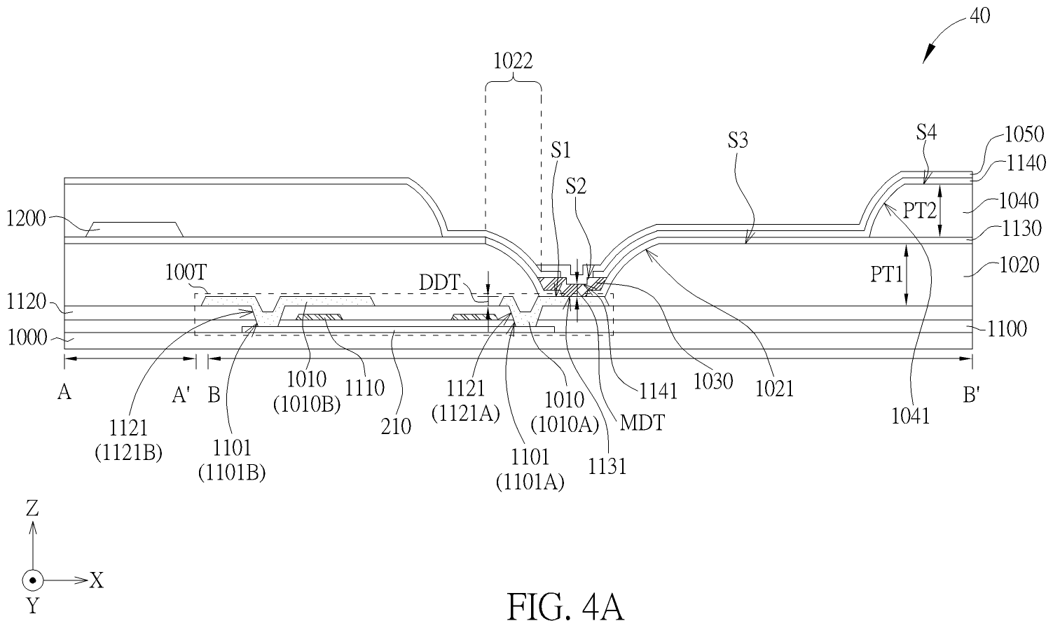

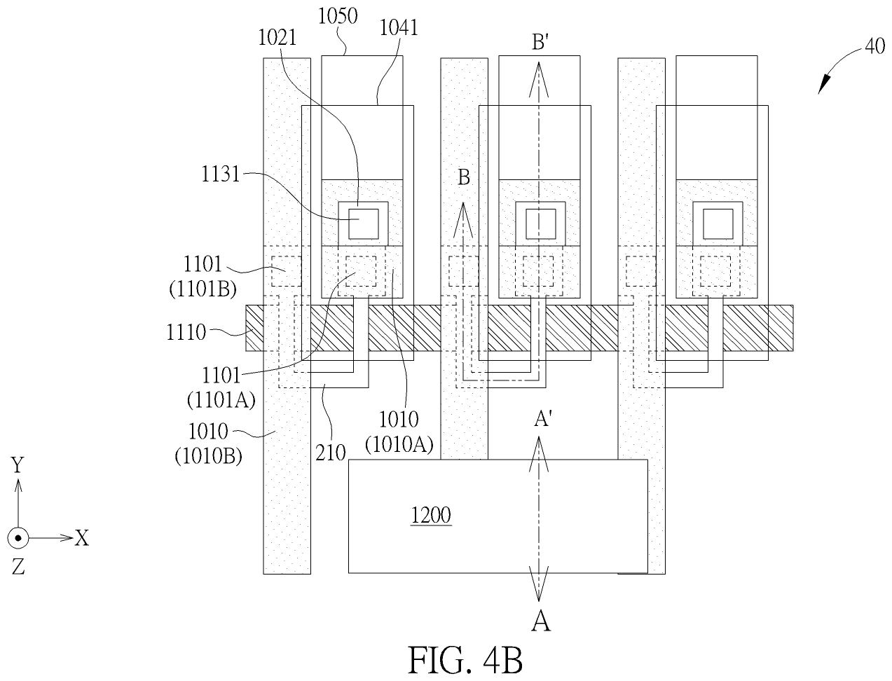

FIG. 4A is a side view of a pixel along tangent lines A-A′ and B-B′ in an electronic device 40 according to some embodiments of the present disclosure. FIG. 4B is a top view of a plurality of pixels in the electronic device 40 according to some embodiments of the present disclosure, wherein the pixel in which the tangent lines A-A′ and B-B′ are drawn may correspond to the pixel in FIG. 4A.

As shown in FIG. 4A, the X axis, Y axis and Z axis are perpendicular to each other, wherein the Z axis is the normal direction of the substrate 1000. Compared to FIG. 2A, the first opening 1021 may overlap the second opening 1041, and the second opening 1041 may be greater (e.g. much greater) than the first opening 1021. The second electrode layer 1050 may extend from a surface S4 of the second insulating layer 1140 to the surface S3 of the first insulating layer 1020.

As shown in FIG. 4A, the substrate 1000, the first electrode layer 1010A, the first insulating layer 1020, the first opening 1021, the third insulating layer 1130, the third opening 1131, the connecting layer 1030, the light sensing component 1200, the second insulating layer 1040, the second opening 1041, the fourth insulating layer 1140, the fourth opening 1141 and the second electrode layer 1050 may be sequentially disposed in the electronic device 40. That is, the connecting layer 1030 is disposed before the second insulating layer 1040 is disposed. By disposing the connecting layer 1030 before disposing the second insulating layer 1040, the second electrode layer 1050 may be connected to the connecting layer 1030 via the second opening 1041 and/or the fourth opening 1141, and the connecting layer 1030 may be connected to the first electrode layer 1010A via the first opening 1021 and/or the third opening 1131. In addition, by disposing the connecting layer 1030, the fourth opening 1141 may be indirectly connected to the third opening 1131 via the connecting layer 1030. Thus, the fourth opening 1141 and the third opening 1131 may not be aligned; that is, the center of the fourth opening 1141 and the center of the third opening 1131 do not overlap. As shown in FIG. 4A, the first opening 1021 overlaps the second opening 1041, and the second opening 1041 is greater than the first opening 1021.

As shown in FIG. 4B, the X axis, Y axis and Z axis are perpendicular to each other, wherein the Z axis is the normal direction of the substrate 1000. Refer to FIG. 4A for a disposal of the electronic device 40 in FIG. 4B, and details are not repeated herein. For simplicity, only the third opening 1131 (of the third opening 1131 and the fourth opening 1141) in FIG. 4A is shown in FIG. 4B. The fourth opening 1141 may be greater than the third opening 1131, the fourth opening 1141 may be smaller than the third opening 1131 or the fourth opening 1141 may be equal to the third opening 1131. It is noted that the second electrode layer 1050 is connected to the first electrode layer 1010A via the connecting layer 1030 in FIG. 4A (not shown in FIG. 4B). The first opening 1021 overlaps the second opening 1041, and the second opening 1041 is greater than the first opening 1021. In some embodiments, the width of the first opening 1021 may be 4-8 μm, but is not limited thereto. The width of the second opening 1041 may be 10-25 μm, such as 16-25 μm, but is not limited thereto. In some embodiments, the width of the second opening 1041 may be at least twice the width of the first opening 1021.

The following embodiments may be used in various figures in the present disclosure.

The electronic device may include a display device, an antenna device, a sensing device, or a splicing device, but is not limited thereto. The electronic device may be a bendable electronic device or a flexible electronic device. The electronic device may include, for example, a liquid crystal light emitting diode (LED). The light emitting diode may include, for example, an organic LED (OLED), a sub-millimeter LED (mini LED), a micro LED or a quantum dot LED (quantum dot (QD), e.g. QLED, QDLED), fluorescence, phosphor or other suitable materials, but is not limited thereto. The above materials may be arranged and combined arbitrarily. The antenna device may be, for example, a liquid antenna, but is not limited thereto. The splicing device may be, for example, a display splicing device or an antenna splicing device, but is not limited thereto. It is noted that the electronic device may be any arrangement and combination of the above devices, but is not limited thereto.

In some embodiments, the first insulating layer 1020 or the second insulating layer 1040 may include a planarization layer, but is not limited thereto. In some embodiments, a material of the planarization layer may include an organic material with a higher light transmittance and/or used for forming a thick film, such as resist, an OC, other suitable materials or combination thereof, but is not limited thereto. In some embodiments, the third insulating layer 1130 or the fourth insulating layer 1140 may include a passivation layer, which may be patterned with a photoresist, but is not limited thereto. In some embodiments, a material of the passivation layer may include an inorganic material, but is not limited thereto.

It is noted that, for purposes of illustrative clarity and ease of understanding, various figures of this disclosure label a portion of the same (i.e. shown with the same pattern) components, layers or openings in this disclosure. For example, the layers shown with diagonal stripes from the upper left to the lower right are all the gate lines 1110, the components shown with dot patterns are all the conductive layers 1010, and the layers shown with diagonal stripes from the upper right to the lower left are all the connecting layers 1030. In addition, only the component of one pixel, the layer of the one pixel or the opening of the one pixel are labeled in FIGS. 1B, 2B, 3B and 4B in the present disclosure. Labels of the pixel may be used for other pixels in the same figure.

It is noted that the technical features in the above embodiments can be replaced, recombined or mixed with one another to constitute another embodiment without departing from the spirit of the present disclosure.

To sum up, in the electronic device of the present disclosure, at least a portion of the second electrode layer 1050 is disposed in the second opening 1041 of the second insulating layer 1040, and is electrically connected to the first electrode layer 1010A via the connecting layer 1030 disposed in the first opening 1021 of the first insulating layer 1020. Thus, according to some embodiments, the connection between the two electrode layers may have a higher reliability. According to some embodiments, the first opening 1021 and the second opening 1041 do not need to be aligned, which may simplify the manufacturing process.

The above description details various embodiments of the present disclosure, but is not intended to limit the present disclosure.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate;
a first electrode layer disposed on the substrate;
a first insulating layer disposed on the first electrode layer, having a first opening to expose a surface of the first electrode layer;
a connecting layer, wherein at least a portion of the connecting layer is disposed in the first opening, a sidewall exposure of the first opening is exposed, and the connecting layer is electrically connected to the first electrode layer;
a second insulating layer disposed on the first insulating layer, having a second opening to expose a surface of the connecting layer; and
a second electrode layer disposed on the second insulating layer, wherein at least a portion of the second electrode layer is disposed in the second opening, and is electrically connected to the connecting layer.

2. The electronic device of claim 1, wherein at least a portion of the second insulating layer is disposed in the first opening.

3. The electronic device of claim 1, wherein at least a portion of the second insulating layer is disposed on the sidewall exposure.

4. The electronic device of claim 1, wherein the first opening does not overlap the second opening.

5. The electronic device of claim 1, wherein the first opening overlaps the second opening.

6. The electronic device of claim 1, wherein the second opening is greater than the first opening.

7. The electronic device of claim 1, wherein the second electrode layer extends from a surface of the second insulating layer to a surface of the first insulating layer.

8. The electronic device of claim 1, comprising:
a third insulating layer disposed on the first insulating layer, having a third opening, wherein at least a portion of the third insulating layer is disposed in the first opening, and at least a portion of the connecting layer is disposed in the third opening.

9. The electronic device of claim 1, comprising:
a fourth insulating layer disposed on the second insulating layer, having a fourth opening, wherein at least a portion of the second electrode layer is disposed in the fourth opening.

10. The electronic device of claim 1, comprising:
a light sensing component disposed between the first insulating layer and the second insulating layer.
